(19) United States
(12) Patent Application Publication
(10) Pub. No.: US 2014/0176118 A1
(43) Pub. Date: Jun. 26, 2014

(54) Differential Current Sensor

(71) Applicant: ELECTRO-MOTIVE DIESEL, INC., LaGrange, IL (US)

(72) Inventor: John E. Madsen, Lemont, IL (US)

(73) Assignee: Electro-Motive Diesel, Inc., LaGrange, IL (US)

(21) Appl. No.: 13/721,577

(22) Filed: Dec. 20, 2012

(51) Int. Cl. G01R 15/20

(52) U.S. Cl. CPC G01R 15/202
USPC 324/117 H

(57) ABSTRACT

A differential current sensor is disclosed. The differential current sensor includes a holder having a plurality of primary wire conduits, a secondary wire located in magnetic proximity to the primary wire conduits, and a magnetic core having a first end receiving a plurality of windings of the secondary wire, and a second, opposing end having a gap.

### TECHNICAL FIELD

This disclosure relates generally to a current sensor and more particularly to a differential current sensor.

### BACKGROUND

Differential current sensors are well known devices for determining the presence of unwanted currents, for example in multi-phase wiring. As an example of the use of differential current sensors, three-phase devices such as motors and generators, if monitored for current flow at a specific location of the three wires needed to provide three phases of power, should exhibit under normal operating conditions a balanced state of no current. However, if a fault may exist at some portion of the device (such as a partial short to ground), a differential current sensor will detect and measure some current flow.

U.S. Pat. No. 7,193,408 (the '408 patent) describes an open-loop electric current differential sensor. This sensor is used to measure current flowing in a conductor due to a fault condition. Typically, the sensor includes a holder having a plurality of primary wire conduits, a secondary wire located in magnetic proximity to the primary wire conduits, and a magnetic core having a first end receiving a plurality of windings, for example three, of the secondary wire, the windings being located on the same end as the gap. The gap includes a Hall Effect sensor that senses induced current flow from the secondary wire windings. The plurality of windings described by the '408 patent includes very few actual windings, which requires the need for a highly sensitive current sensing device, which results in a very expensive differential current sensor. However, there are many applications in which a low cost differential current sensor may be preferred.

The present disclosure is directed to overcoming one or more of the problems as set forth above.

### SUMMARY

In one aspect of the present disclosure, a differential current sensor is disclosed. The differential current sensor includes a holder having a plurality of primary wire conduits, a secondary wire located in magnetic proximity to the primary wire conduits, and a magnetic core having a first end receiving a plurality of windings of the secondary wire, and a second, opposing end having a gap.

In another aspect of the present disclosure an electrical device having a differential current sensor is disclosed. The electrical device includes a plurality of primary wires providing current to the electrical device, a holder having a plurality of primary wire conduits positioning the primary wires, a secondary wire located in magnetic proximity to the primary wires, and a magnetic core having a first end receiving a plurality of windings of the secondary wire, and a second, opposing end having a gap.

### BRIEF DESCRIPTION OF THE DRAWINGS

FIG. 1 is a diagrammatic illustration of a locomotive suitable for use with the present disclosure; and

FIG. 2 is a diagrammatic illustration of an embodiment of the present disclosure.

### DETAILED DESCRIPTION

The present disclosure describes a differential current sensor 100 suitable for use in determining differential current in an electrical device 132, such as a three-phase motor 134.

Examples of motors suited for use with a differential current sensor may include traction motors, for example for locomotives. However, it is noted that other types of motors and other types of electrical devices, such as generators, transformers, and the like, may also benefit from use of the differential current sensor of the present disclosure.

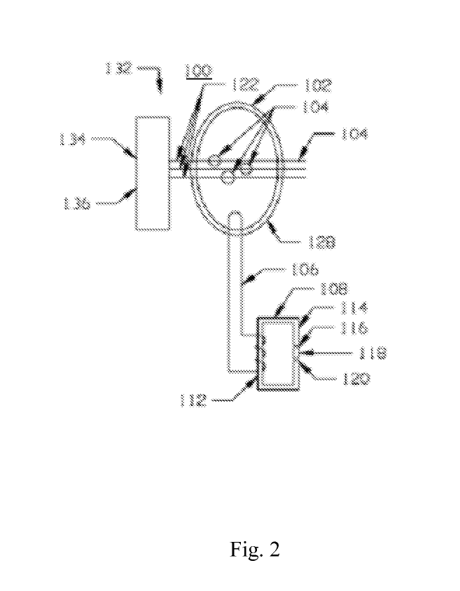

The differential current sensor 100 may include a holder 102 which has a plurality of primary wire conduits 104 which may be located proximate each other. For example, as shown in FIG. 2, the holder 102 has primary wire conduits 104 located in a triangular arrangement. However, the primary wire conduits 104 may be located in other arrangements, such as linear.

A secondary wire 106 may be located in magnetic proximity to the primary wire conduits 104. The secondary wire 106 may be a single loop, as shown in FIG. 2, or may have multiple loops, or may terminate near the primary wire conduits 104 without loops.

The secondary wire 106 is positioned to be in close proximity to a magnetic core 108, for example by a plurality of windings 112 about a first end 110 of the magnetic core 108. In one embodiment, the plurality of windings 112 includes greater than 100 windings. In another embodiment, the plurality of windings 112 includes greater than 500 windings. In yet another embodiment, the plurality of windings 112 includes greater than 1,000 windings. It is noted that any number of windings 112 may be used, provided that the number is sufficient for use with the present disclosure.

The magnetic core 108 includes a second end 114 opposing the first end 110, as illustrated in FIG. 2. The second end 114 includes a gap 116. By use of a plurality of windings 112 having many windings as described above, it is not necessary to locate the windings in close proximity to the gap 116 since the large number of windings results in a significant induced current in the magnetic core 108.

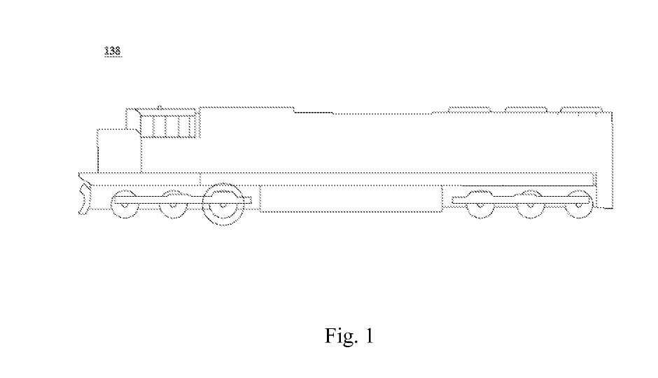

The gap 116 may include an open loop sensor 118 used to sense current in an electrical device such as a traction motor 136, as shown in FIG. 2. In one embodiment, an open loop sensor 118 may be a Hall Effect sensor 120. In another embodiment, the open loop sensor 118 may be a thin piece of semiconductor material through which current is passed, such that when no magnetic field is present, the current distribution is uniform and no potential difference is detected across outputs (such as voltage supply and ground). For example, a locomotive 139 may provide the voltage supply, as shown in FIG. 1.

The gap 116 is positioned on the second end 114 of the magnetic core 108, where the magnetic core 108 may be laminated, or otherwise constructed to minimize eddy currents, as shown in FIG. 2.

On the first end of the magnetic core 108 and opposite the gap 116 are the plurality of windings 112, as illustrated in FIG. 2. On at least one end of the windings 112 is the secondary wire 106, which winds around the holder 102. In one embodiment, the holder 102 may be magnetic 128. In another embodiment, the holder 102 may be metallic. The secondary wire 106 is located in close proximity to primary wires 122.

### INDUSTRIAL APPLICABILITY

As an application of the present disclosure, a differential current sensor 100 is used for measuring unwanted currents such as faults, in multi-phase wiring devices. Typically, in three-phase devices, such as motors and generators are used to detect current flow at discrete locations within the three wires, which feed the three phases of power. Generally, under normal conditions, a balanced state will be achieved and no current is found. However, if a fault is located somewhere device (such as a partial short to ground), a differential current sensor will detect and measure some current flow. The differential current sensor 100 includes a holder 102 having a plurality of primary wire conduits 104, a secondary wire 106 located in magnetic proximity to the primary wire conduits 104, and a magnetic core 108 having a first end 110 receiving a plurality of windings 112 of the secondary wire 106, the windings being located on the same end as the gap 116. The gap 116 includes a Hall Effect sensor 120 that senses induced current flow from the secondary wire windings 106. The plurality of windings 112 may be few in number. This may result in a more accurate current sensing device, which results in a very expensive differential current sensor. However, there are many applications in which a low cost, albeit less accurate differential current sensor may be preferred.

In the embodiment shown in FIG. 1, the magnetic core 108 includes a second end 114 opposing the first end 110, as illustrated in FIG. 2. The second end 114 includes a gap 116. By use of a plurality of windings 112 having many windings as described above, it is not necessary to locate the windings in close proximity to the gap 116 since the large number of windings results in a significant induced current in the magnetic core 108. This may result is a lower cost device.

Other aspects can be obtained from a study of the drawings, the specification, and the appended claims.

What is claimed is:

1. A differential current sensor comprising:
a holder having a plurality of primary wire conduits located proximate each other;
a secondary wire located in magnetic proximity to the primary wire conduits; and
a magnetic core having a first end receiving a plurality of windings of the secondary wire, and a second, opposing end having a gap.

2. The differential current sensor of claim 1, further comprising an open loop sensor located in the gap.

3. The differential current sensor of claim 2, wherein the open loop sensor is a Hall Effect sensor.

4. The differential current sensor of claim 1, wherein the plurality of windings includes greater than 100 windings.

5. The differential current sensor of claim 1, wherein the plurality of windings includes greater than 500 windings.

6. The differential current sensor of claim 1, wherein the plurality of windings includes greater than 1000 windings.

7. The differential current sensor of claim 1, wherein the magnetic core is laminated.

8. The differential current sensor of claim 1, wherein the holder includes a metallic component.

9. The differential current sensor of claim 8, wherein the secondary wire includes at least one winding around the metallic component and in magnetic proximity to the primary wire conduits.

10. An electrical device having a differential current sensor, comprising:
a plurality of primary wires providing current to the electrical device;
a holder having a plurality of primary wire conduits positioning the primary wires proximate each other;
a secondary wire located in magnetic proximity to the primary wires; and
a magnetic core having a first end receiving a plurality of windings of the secondary wire, and a second, opposing end having a gap.

11. The electrical device of claim 10, wherein the electrical device is a motor.

12. The electrical device of claim 11, wherein the motor is a traction motor for a locomotive.
